(19) United States
(12) Patent Application Publication
(10) Pub. No.: US 2012/0252210 A1
(43) Pub. Date: Oct. 4, 2012

(54) METHOD FOR MODIFYING METAL CAP LAYERS IN SEMICONDUCTOR DEVICES

(75) Inventor: Kazuhito Tohnoe, Kai (JP)

(73) Assignee: Tokyo Electron Limited, Tokyo (JP)

(21) Appl. No.: 13/076,016

(22) Filed: Mar. 30, 2011

(51) Int. Cl. H01L 21/28

(52) U.S. Cl. 438/658; 257/E21.158

(57) ABSTRACT

A method for forming a semiconductor device with improved electromigration (EM) and stress migration (SM) properties. The method includes providing a planarized patterned substrate containing a copper (Cu) metal surface and a low-k dielectric layer surface, selectively depositing a metal cap layer on the Cu metal surface, and modifying the metal cap layer by exposing the metal cap layer to a process gas containing ammonia (NH₃) gas without plasma excitation. The method further includes forming a dielectric barrier film on the modified metal cap layer and on the dielectric layer surface, and exposing the dielectric barrier film to a gaseous oxidizing environment, where the dielectric barrier film and the modified metal cap layer prevent oxidation of the Cu metal surface when the dielectric barrier film is exposed to the gaseous oxidizing environment.

### FIELD OF THE INVENTION

The present invention relates to semiconductor processing and semiconductor devices, and more particularly, to a method of modifying metal cap layers in copper (Cu) metallization of semiconductor devices to improve electromigration (EM) and stress migration (SM) in bulk Cu metal.

### BACKGROUND OF THE INVENTION

An integrated circuit contains various semiconductor devices and a plurality of conducting metal paths that provide electrical power to the semiconductor devices and allow these semiconductor devices to share and exchange information. Within the integrated circuit, metal layers are stacked on top of one another using intermetal or interlayer dielectric layers that insulate the metal layers from each other. Normally, each metal layer must form an electrical contact to at least one additional metal layer. Such electrical contact is achieved by etching a hole (i.e., a via) in the interlayer dielectric that separates the metal layers, and filling the resulting via with a metal to create an interconnect. A “via” normally refers to any recessed feature such as a hole, line or other similar feature formed within a dielectric layer that, when filled with metal, provides an electrical connection through the dielectric layer to a conductive layer underlying the dielectric layer. Similarly, recessed features connecting two or more vias are normally referred to as trenches.

Use of Cu metal in multilayer metallization schemes for manufacturing integrated circuits has created several problems that require solutions. For example, high mobility of Cu atoms in dielectric materials and Si can result in migration of Cu atoms into those materials, thereby forming electrical defects that can destroy an integrated circuit. Therefore, Cu metal layers, Cu filled trenches, and Cu filled vias are normally encapsulated with a barrier layer to prevent Cu atoms from diffusing into the dielectric materials. Barrier layers are normally deposited on trench and via sidewalls and bottoms prior to Cu deposition, and may include materials that are preferably non-reactive and immiscible in Cu, provide good adhesion to the dielectrics materials and can offer low electrical resistivity.

The electrical current density in an integrated circuit's interconnects significantly increases for each successive technology node due to decreasing minimum feature sizes. Because electromigration (EM) and stress migration (SM) lifetimes are inversely proportional to current density, EM and SM have fast become critical challenges. EM lifetime in Cu dual damascene interconnect structures is strongly dependent on atomic Cu transport at the interfaces of bulk Cu metal and surrounding materials which is directly correlated to adhesion at these interfaces. New materials that provide better adhesion and better EM lifetime have been studied extensively. For example, a cobalt-tungsten-phosphorus (CoWP) layer has been selectively deposited on bulk Cu metal using an electroless plating technique. The interface of CoWP and bulk Cu metal has superior adhesion strength that yields longer EM lifetime. However, maintaining acceptable deposition selectivity on bulk Cu metal, especially for tight pitch Cu wiring, and maintaining good film uniformity, has affected acceptance of this complex process. Furthermore, wet process steps using acidic solution may be detrimental to the use of CoWP.

Therefore, new methods are required for forming metal-containing cap layers that provide good adhesion to Cu metal and improved EM and SM properties of bulk Cu metal.

### SUMMARY OF THE INVENTION

Embodiments of the invention provide a method for forming a semiconductor device with a modified metal cap layer in Cu metallization to improve electromigration (EM) and stress migration (SM) in the device. The metal cap layer can contain ruthenium (Ru), rhodium (Rh), platinum (Pt), palladium (Pd), or an alloy thereof.

According to one embodiment of the invention, a method is provided for forming a semiconductor device. The method includes providing a planarized patterned substrate containing a Cu metal surface and a low dielectric constant (low-k) dielectric layer surface, selectively depositing a metal cap layer on the Cu metal surface, and modifying the metal cap layer by exposing the metal cap layer to a process gas containing ammonia (NH₃) gas without plasma excitation. The method further includes forming a dielectric barrier film on the modified metal cap layer and on the dielectric layer surface, exposing the dielectric barrier film to a gaseous oxidizing environment, where the dielectric barrier film and the modified metal cap layer prevent oxidation of the Cu metal surface when the dielectric barrier film is exposed to the gaseous oxidizing environment.

According to another embodiment of the invention, a method is provided for forming a semiconductor device. The method includes providing a planarized patterned substrate containing a Cu metal surface and a dielectric layer surface, selectively depositing a metal cap layer on the Cu metal surface, wherein the metal cap layer comprises a metal selected from ruthenium (Ru), rhodium (Rh), platinum (Pt), palladium (Pd), and an alloy thereof, and modifying the metal cap layer by exposing the metal cap layer to a process gas containing ammonia (NH₃) gas without plasma excitation. The method further includes forming a dielectric barrier film containing silicon (Si) on the modified metal cap layer and on the low-k dielectric layer surface and exposing the dielectric barrier film to a gaseous oxidizing environment, where a combined thickness of the metal cap layer and the dielectric barrier film is less than 20 nm, and where the method of forming a semiconductor device by forming a modified metal cap layer prevents oxidation of the Cu metal surface when compared to a method of forming a semiconductor device using an unmodified metal cap layer.

### BRIEF DESCRIPTION OF THE DRAWINGS

A more complete appreciation of the invention and many of the attendant advantages thereof will become readily apparent with reference to the following detailed description, particularly when considered in conjunction with the accompanying drawings, in which:

FIGS. 1A-1D show schematic cross-sectional views of forming a semiconductor device according to one embodiment of the invention;

FIG. 2 is a flow diagram for forming a semiconductor device according to an embodiment of the invention;

FIG. 3 shows oxidation resistance results for a dielectric barrier film and a modified Ru metal cap layer according to an embodiment of the invention;

FIG. 4 depicts a schematic view of a thermal processing system for modifying a metal cap layer according to an embodiment of the invention;

FIG. 5 depicts a schematic view of a thermal chemical vapor deposition (TCVD) system for depositing a Ru metal film according to an embodiment of the invention; and

FIG. 6 depicts a schematic view of another TCVD system for depositing a Ru metal film according to another embodiment of the invention.

### DETAILED DESCRIPTION OF SEVERAL EMBODIMENTS

Embodiments of the invention provide a method for forming a modified metal cap layer in Cu metallization of a semiconductor device to increase the oxidation resistance of the metal cap layer and improve EM and SM of the device. One skilled in the relevant art will recognize that the various embodiments may be practiced without one or more of the specific details, or with other replacement and/or additional methods, materials, or component. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Furthermore, it is understood that the various embodiments shown in the figures are illustrative representations and are not necessary drawn to scale.

Reference throughout this specification to “one embodiment” means that a particular feature, structure, material, or characteristic described in connection with the embodiment is included in at least one embodiment of the invention, but do not denote that they are present in every embodiment. Thus, the appearances of the phrase “one embodiment” in various places throughout this specification are not necessarily referring to the same embodiment of the invention.

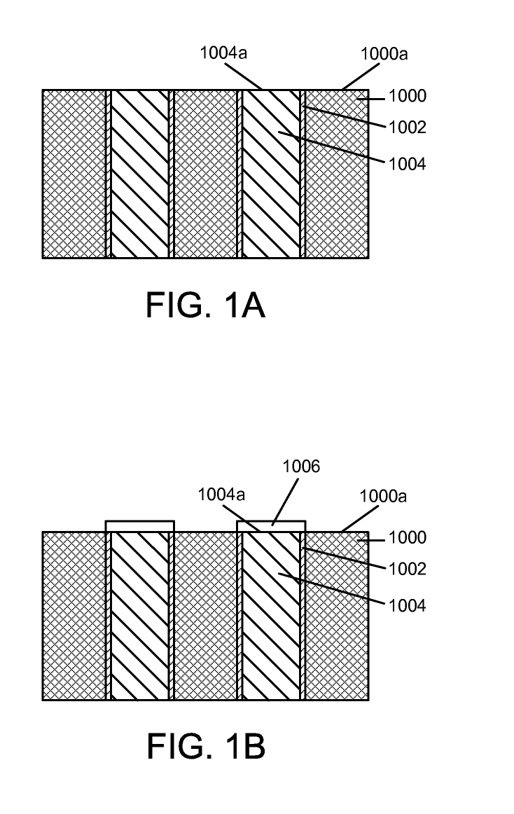

FIGS. 1A-1D show schematic cross-sectional views of forming a semiconductor device according to one embodiment of the invention. FIG. 1A shows a patterned substrate containing a plurality of recessed features in a low-k dielectric layer 1000, a diffusion barrier layer 1002 in the recessed features, and Cu metal layers 1004 filling the recessed features. The low-k dielectric layer 1000 can contain a low-k dielectric material having a lower dielectric constant than SiO₂ (k˜3.9), for example fluorinated silicon glass (FSG), carbon doped oxide, a polymer, a SiCOH-containing low-k material, a non-porous low-k material, a porous low-k material, a CVD low-k material, a spin-on dielectric (SOD) low-k material, or any other suitable low-k dielectric material. The diffusion barrier layer 1002 can, for example, contain a tantalum (Ta)-containing layer (e.g., Ta, TaC, TaN, or TaCN, or a combination thereof), a titanium (Ti)-containing layer (e.g., Ti, TiN, or a combination thereof), or a tungsten (W)-containing layer (e.g., W, WN, or a combination thereof). Although not shown in FIG. 1A, an adhesion layer, e.g., a Ru metal layer, may be located between the diffusion barrier layer 1002 and the Cu metal layer 1004 in the recessed features.

Still referring to FIG. 1A, the patterned substrate has been planarized to form a Cu metal layer surface 1004a and a low-k dielectric layer surface 1000a. Cu filling of the recessed feature may be performed by a Cu plating process, for example by an electrochemical plating process or by an electroless plating process, and the planarization may be performed by chemical mechanical polishing (CMP) following the Cu plating process. The CMP process may be optimized for Cu removal with high selectivity to the low-k dielectric layer 1000. The planarization removes excess Cu metal from the patterned substrate following the Cu filling process and further removes the diffusion barrier layer 1002 from the low-k dielectric layer surface 1000a. CMP and Cu plating processes are well known to those skilled in the art.

Following the planarization, the low-k dielectric layer surface 1000a and the Cu metal layer surface 1004a may be treated to remove residue and surface oxidation from those surfaces prior to depositing a metal cap layer on the Cu metal layer surface 1004a. Exemplary treatments are described in U.S. Pat. Nos. 7,829,454, and 7,776,740, and U.S. patent application Ser. Nos. 12/240,894, 12/414,917, and 12/749,783, the contents of which are herein incorporated by reference.

In FIG. 1A, the patterned substrate may be a part of a damascene interconnect structure containing a high-aspect-ratio recessed feature. The feature can have an aspect ratio (depth/width) greater than or equal to about 2:1, for example 3:1, 4:1, 5:1, 6:1, 12:1, 15:1, or higher. The feature can have a width of about 200 nn (nm=10⁻⁹ m), or less, for example 150 nm, 100 nm, 65 nm, 45 nm, 32 nm, 20 nm, or smaller. However, embodiments of the invention are not limited to these aspect ratios or feature widths, as other aspect ratios and feature widths may be utilized. According to one embodiment of the invention, a dual damascene interconnect structure contains a trench and a via formed in the patterned substrate. It will be understood that embodiments of the invention may be applied to simple and complicated damascene interconnect structures and other types of patterned substrates containing recessed features filled with Cu metal.

FIG. 1B shows a metal cap layer 1006 selectively deposited on the Cu metal layer surface 1004a. The metal cap layer 1006 can contain ruthenium (Ru), rhodium (Rh), platinum (Pt), palladium (Pd), and an alloy thereof. Using a Ru metal cap layer 1006 as an example, the Ru metal cap layer 1006 may be deposited by a thermal chemical vapor deposition (TCVD) process in a process chamber without plasma excitation using a process gas containing Ru₃(CO)₁₂ precursor vapor and CO carrier gas. An exemplary Ru metal TCVD process using a Ru₃(CO)₁₂ precursor and a CO carrier gas is described U.S. Pat. No. 7,270,848, the contents of which is herein incorporated by reference. In another example, the metal cap layer 1006 may be deposited by a CVD process utilizing a ruthenium metalorganic precursor. Exemplary ruthenium metalorganic precursors include (2,4-dimethylpentadienyl)(ethylcyclopentadienyl)ruthenium (Ru(DMPD)(EtCp)), bis(2,4-dimethylpentadienyl)ruthenium (Ru(DMPD)₂), 4-dimethylpentadienyl)(methylcyclopentadienyl)ruthenium (Ru(DMPD)(MeCp)), and bis(ethylcyclopentadienyl)ruthenium (Ru(EtCp)₂), as well as combinations of these and other precursors.

In some examples, an average thickness of the metal cap layer 1006 can be between 1 nm and 15 nm, or between 2 nm and 10 nm, for example about 2 nm, 3 nm, 4 nm, 5 nm, 6 nm, 7 nm, 8 nm, 9 nm, or 10 nm. However, embodiments of the invention are not limited to those thicknesses and a thicker metal cap layer 1006 may be utilized. Deposition of the metal cap layer 1006 on the Cu metal layer surface 1004a can be substantially selective relative to the low-k dielectric layer surface 1000a. In other words, the metal is exclusively or highly preferentially deposited on the Cu metal layer surface 1004a compared to on the low-k dielectric layer surface 1000a.

As described above, EM lifetime in Cu dual damascene interconnect structures is strongly dependent on atomic Cu transport at the interfaces of bulk Cu metal and surrounding materials which is directly correlated to adhesion at these interfaces. The current inventors have realized that weak adhesion that has been observed between the Cu metal layer 1004 and a Ru metal cap layer 1006 is likely due to oxidation of the Cu metal layer 1004 at the surface 1004a during subsequent processing of the patterned substrate depicted in FIG. 1B. This is likely due to limited oxidation barrier properties of the metal cap layer 1006 which can allow for oxygen diffusion thorough the metal cap layer 1006 and result in oxidation of the Cu metal layer 1004 at the surface 1004a, thereby weakening the adhesion between the Cu metal layer 1004 and the metal cap layer 1006.

The current inventors have realized that the metal cap layer 1006 may be modified by gas phase exposure of a process gas containing NH₃ without plasma excitation to form a modified metal cap layer. The modified metal cap layer has improved oxidation barrier properties compared to the unmodified metal cap layer 1006 when exposed to a gaseous oxidizing environment such as air. Preventing or reducing oxidation of the surface 1004a of the Cu metal layer 1004 maintains strong adhesion between the modified metal cap layer 1006 and the Cu metal layer 1004 and is expected to yield longer EM lifetime.

FIG. 1C shows gas phase exposure of the patterned substrate by a process gas containing NH₃ gas 1012 without plasma excitation. The NH₃ gas exposure modifies the metal cap layer 1006 and forms a modified metal cap layer 1010 on the Cu metal layer 1004. Although not wishing to be bound by theory, the NH₃ gas exposure is thought to densify the metal cap layer 1006 by interacting with grain boundaries in the metal cap layer 1006 and incorporating nitrogen into the metal cap layer 1006. According to some embodiments of the invention, the NH₃ gas exposure may be performed using pure NH₃ gas, or NH₃ gas and an inert gas (e.g., a noble gas or N₂). The NH₃ gas exposure may be performed for a time period between 10 seconds and 30 seconds, between 30 seconds and 60 seconds, or between 60 seconds and 120 seconds, or greater than 120 seconds. The temperature of the patterned substrate containing the metal cap layer 1006 may be maintained above room temperature during the NH₃ gas exposure, for example between 30° C. and 50° C., between 50° C. and 100° C., between 100° C. and 200° C., between 200° C. and 300° C., between 300° C. and 400° C., or higher.

Following the formation of the modified metal cap layer 1010 depicted in FIG. 1C, the partially manufactured semiconductor device is further processed. FIG. 1D shows a dielectric barrier 1014 formed on the modified metal cap layer 1010 and on the low-k dielectric layer surface 1000a. The dielectric barrier film 1014 can, for example, include a Si-containing film such as silicon nitride (SiN), silicon carbide (SiC), or silicon carbonitride (SiCN), or a combination thereof. The dielectric barrier film 1014 contributes to the effective dielectric constant of the semiconductor device, and since the material of the dielectric barrier film 1014 normally has a higher dielectric constant that the low-k dielectric layer 1000, the dielectric barrier film 1014 needs to be very thin, on the order of few nm, for example less than 20 nm, less than 15 nm, less than 10 nm, or even less than 5 nm.

The partially manufactured semiconductor device schematically depicted in FIG. 1D is further processed to form a completed semiconductor device, for example an integrated circuit. However, the further processing may include exposure of the partially manufactured semiconductor device to a gaseous oxidizing environment where the dielectric barrier film 1014 and the modified metal cap layer 1010 are required to prevent or reduce oxidation of the Cu metal surface 1004a when exposed to the oxidizing environment. The gaseous oxidizing environment can include air exposure, exposure to oxygen-containing process gases during further processing of the partially manufactured semiconductor device, or exposure to oxygen-containing background gases (e.g., H₂O, O₂) that are normally present in process chambers and transfer systems configured for transferring wafers between process chambers.

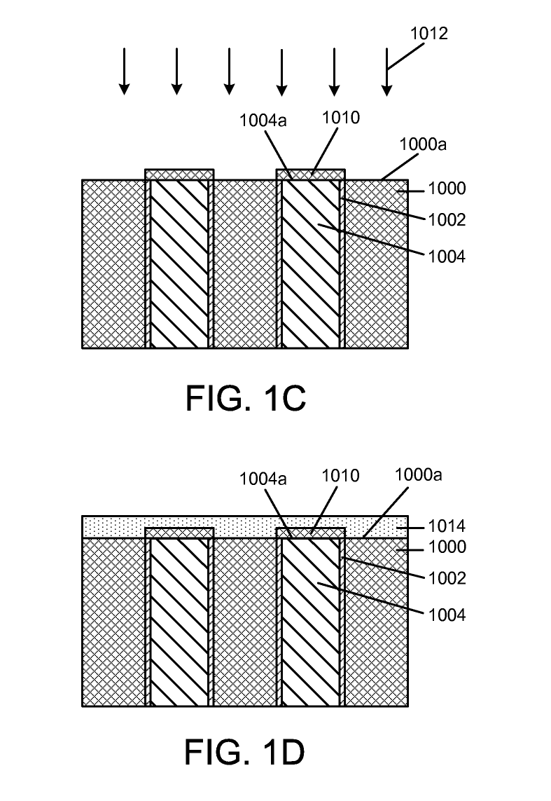

FIG. 2 is a flow diagram for forming a semiconductor device according to an embodiment of the invention. Referring also to FIGS. 1A-1D, the process flow 250 includes in 252, providing a planarized patterned substrate containing a Cu metal surface 1004a and a low-k dielectric layer surface 1000a.

In 254, a metal cap layer 1006 is selectively deposited on the Cu metal surface 1004a. The metal cap layer 1006 can contain Ru, Rh, Pt, Pd, or an alloy thereof, and the metal cap layer 1006 may be deposited by a thermal chemical vapor deposition (TCVD) process without plasma excitation.

In 256, the metal cap layer 1006 is modified by exposing the metal cap layer 1006 to a process gas containing NH₃ gas 1012 without plasma excitation. The NH₃ gas exposure may be performed using pure NH₃ gas, or using NH₃ gas and an inert gas, in combination with maintaining the temperature of the patterned substrate above room temperature. According to some embodiments of the invention, both the metal cap deposition in 254 and the modifying in 256 may be performed without plasma excitation that could damage the low-k dielectric layer surface 1000a, the Cu metal surface 1004a, and the metal cap layer 1006.

In 258, a dielectric barrier film 1014 is formed on the modified metal cap layer 1010 and on the low-k dielectric layer surface 1000a. The dielectric barrier film 1014 can, for example, include a Si-containing film such as silicon nitride (SiN), silicon carbide (SiC), or silicon carbonitride (SiCN), or a combination thereof.

In 260, the patterned surface is further processed, where the dielectric barrier film is exposed to a gaseous oxidizing environment. According to embodiments of the invention, the dielectric barrier film 1014 and the modified metal cap layer 1010 prevent oxidation of the Cu metal surface when the dielectric barrier film is exposed to the gaseous oxidizing environment.

### Experimental Examples

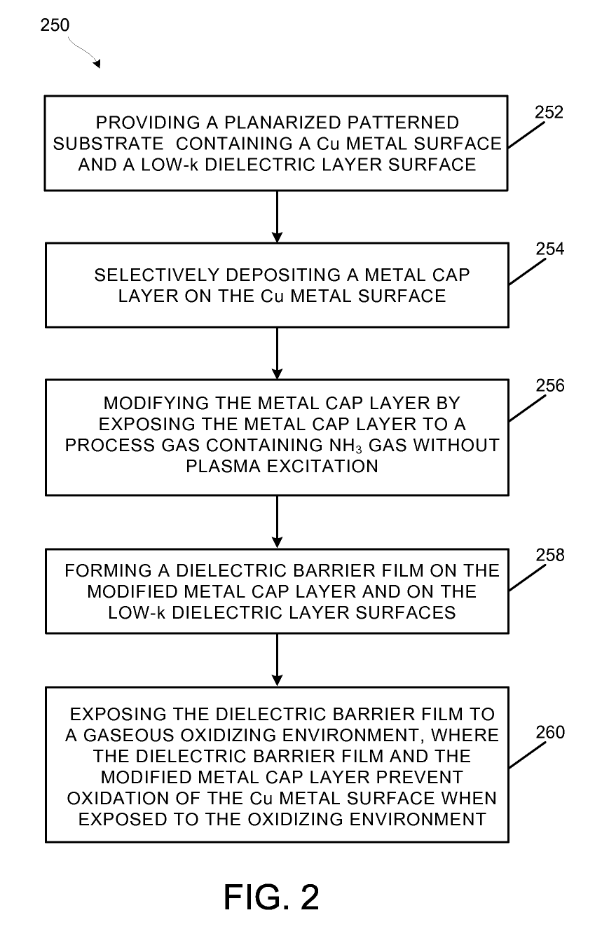

FIG. 3 shows oxidation resistance results for a dielectric barrier film and a modified Ru metal cap layer according to an embodiment of the invention. The SiCN/Ru/Cu test film structures were formed on 300 mm Si wafers. The experimental matrix included unmodified Ru metal cap layers with thicknesses of 5 nm and 10 nm, Ru metal cap layers with thicknesses of 5 nm and 10 nm modified with NH₃ gas exposure without plasma excitation, and SiCN dielectric barrier film thicknesses of 15 nm, 10 nm, 5 nm, and 0 nm (no SiCN dielectric barrier film). The Si wafers with the SiCN/Ru/Cu test structures were subjected to an oxidation barrier test in air at 250° C. for 48 hours. Following the oxidation barrier test, the test structures were evaluated using a scanning electron microscope (SEM) and given a FAILED or PASSED grade. A test structure showing the sign of Cu blistering or film pinholes that indicated oxidation barrier failure of the SiCN/Ru failure received a FAILED grade whereas a test structure showing no change between before and after the oxidation barrier test received a PASSED grade.

FIG. 3 shows that without a SiCN dielectric barrier film, unmodified and modified Ru cap layers having thicknesses of 5 nm and 10 nm failed the oxidation barrier test, and SiCN dielectric barrier films having a thickness of 5 nm and 10 nm on unmodified Ru cap layers having thicknesses of 5 nm and 10 nm also failed the oxidation barrier test. However, SiCN dielectric barrier films having a thickness of 5 nm and 10 nm on modified Ru cap layers having thicknesses of 5 nm and 10 nm passed the oxidation barrier test. Furthermore, thick (15 nm) SiCN dielectric barrier films on unmodified or modified Ru cap layers passed the oxidation barrier test. In summary, the results shown in FIG. 3 demonstrate that modified Ru cap layer with a thickness of 5 nm or 10 nm provide improved oxidation resistance compared to unmodified Ru cap layers with a thickness of 5 nm or 10 nm when combined with SiCN diffusion barriers with a thickness of as little as 5 nm. This enables the use of very thin SiCN dielectric barrier films in the semiconductor device which reduces the effective dielectric constant of the integrated circuit and is expected to increase the EM life time.

Still referring to FIG. 3, according to some embodiments, the Ru metal cap layer can have a thickness less than 15 nm, the SiCN dielectric barrier film can have a thickness less than 15 nm, a combined thickness of the Ru metal cap layer and the SiCN dielectric barrier film can be less than 20 nm.

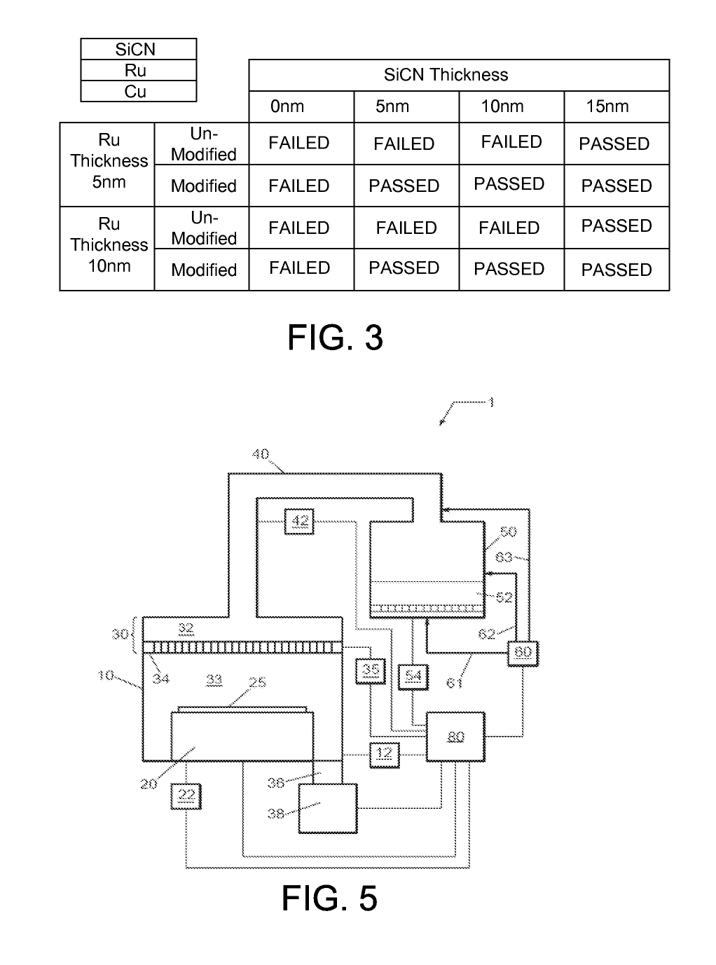

FIG. 4 depicts a schematic view of a thermal processing system for modifying a metal cap layer according to an embodiment of the invention. The thermal processing system 400 includes a process chamber 410 having a substrate holder 420 configured to support a substrate 425. The process chamber 410 further includes an upper assembly 430 (e.g., a showerhead) coupled to process gas supply system 440 and a purge gas supply system 442. The thermal processing system 400 may be configured to process 200 mm substrates, 300 mm substrates, or larger-sized substrates. In fact, it is contemplated that the deposition system may be configured to process substrates, wafers, or LCDs regardless of their size, as would be appreciated by those skilled in the art. Therefore, while aspects of the invention will be described in connection with the processing of a semiconductor substrate, the invention is not limited solely thereto.

The process gas supply system 440 is configured for introducing a process gas 446 to the process chamber 410. According to embodiments of the invention, the process gas 446 can contain NH₃, or NH₃ and an inert gas. Additionally, the purge gas supply system 442 can be configured to introduce a purge gas.

Still referring to FIG. 4, the thermal processing system 400 includes substrate temperature control system 460 coupled to the substrate holder 420 and configured to elevate and control the temperature of substrate 425. Substrate temperature control system 460 comprises temperature control elements, such as a cooling system including a re-circulating coolant flow that receives heat from substrate holder 420 and transfers heat to a heat exchanger system (not shown), or when heating, transfers heat from the heat exchanger system. Additionally, the temperature control elements can include heating/cooling elements, such as resistive heating elements, or thermo-electric heaters/coolers, which can be included in the substrate holder 420, as well as the chamber wall of the process chamber 410 and any other component within the thermal processing system 400. The temperature of the substrate may be maintained above room temperature, for example between 30° C. and 50° C., between 50° C. and 100° C., between 100° C. and 200° C., between 200° C. and 300° C., between 300° C. and 400° C., or higher.

In order to improve the thermal transfer between substrate 425 and substrate holder 420, substrate holder 420 can include a mechanical clamping system, or an electrical clamping system, such as an electrostatic clamping system, to affix substrate 425 to an upper surface of substrate holder 420. Furthermore, substrate holder 420 can further include a substrate backside gas delivery system configured to introduce gas to the back-side of substrate 425 in order to improve the gas-gap thermal conductance between substrate 425 and substrate holder 420. Such a system can be utilized when temperature control of the substrate is required at elevated or reduced temperatures. For example, the substrate backside gas system can comprise a two-zone gas distribution system, wherein the helium gas gap pressure can be independently varied between the center and the edge of substrate 425.

Furthermore, the process chamber 410 is further coupled to a pressure control system 432, including a vacuum pumping system 434 and a valve 436, through a duct 438, wherein the pressure control system 432 is configured to controllably evacuate the process chamber 410 to a pressure suitable for treating substrate 425. The vacuum pumping system 434 can include a turbo-molecular vacuum pump (TMP) or a cryogenic pump capable of a pumping speed up to about 5000 liters per second (and greater) and valve 436 can include a gate valve for throttling the chamber pressure. Moreover, a device for monitoring chamber pressure (not shown) can be coupled to the process chamber 410. The pressure measuring device can be, for example, an absolute capacitance manometer.

Still referring to FIG. 4, controller 470 can comprise a microprocessor, memory, and a digital I/O port capable of generating control voltages sufficient to communicate and activate inputs to thermal processing system 400 as well as monitor outputs from thermal processing system 400. Moreover, the controller 470 may be coupled to and may exchange information with the process chamber 410, substrate holder 420, upper assembly 430, process gas supply system 440, purge gas supply system 442, substrate temperature control system 460, and pressure control system 432. For example, a program stored in the memory may be utilized to activate the inputs to the aforementioned components of the thermal processing system according to a process recipe in order to perform treating process.

However, the controller 470 may be implemented as a general purpose computer system that performs a portion or all of the microprocessor based processing steps of the invention in response to a processor executing one or more sequences of one or more instructions contained in a memory. Such instructions may be read into the controller memory from another computer readable medium, such as a hard disk or a removable media drive. One or more processors in a multi-processing arrangement may also be employed as the controller microprocessor to execute the sequences of instructions contained in main memory. In alternative embodiments, hard-wired circuitry may be used in place of or in combination with software instructions. Thus, embodiments are not limited to any specific combination of hardware circuitry and software.

The controller 470 includes at least one computer readable medium or memory, such as the controller memory, for holding instructions programmed according to the teachings of the invention and for containing data structures, tables, records, or other data that may be necessary to implement the present invention. Examples of computer readable media are compact discs, hard disks, floppy disks, tape, magneto-optical disks, PROMs (EPROM, EEPROM, flash EPROM), DRAM, SRAM, SDRAM, or any other magnetic medium, compact discs (e.g., CD-ROM), or any other optical medium, punch cards, paper tape, or other physical medium with patterns of holes, a carrier wave (described below), or any other medium from which a computer can read.

Stored on any one or on a combination of computer readable media, the present invention includes software for controlling the controller 470, for driving a device or devices for implementing the invention, and/or for enabling the controller to interact with a human user. Such software may include, but is not limited to, device drivers, operating systems, development tools, and applications software. Such computer readable media further includes the computer program product of the present invention for performing all or a portion (if processing is distributed) of the processing performed in implementing the invention.

The computer code devices of the present invention may be any interpretable or executable code mechanism, including but not limited to scripts, interpretable programs, dynamic link libraries (DLLs), Java classes, and complete executable programs. Moreover, parts of the processing of the present invention may be distributed for better performance, reliability, and/or cost.

The term “computer readable medium” as used herein refers to any medium that participates in providing instructions to the processor of the controller 470 for execution. A computer readable medium may take many forms, including but not limited to, non-volatile media, volatile media, and transmission media. Non-volatile media includes, for example, optical, magnetic disks, and magneto-optical disks, such as the hard disk or the removable media drive. Volatile media includes dynamic memory, such as the main memory. Moreover, various forms of computer readable media may be involved in carrying out one or more sequences of one or more instructions to processor of controller for execution. For example, the instructions may initially be carried on a magnetic disk of a remote computer. The remote computer can load the instructions for implementing all or a portion of the present invention remotely into a dynamic memory and send the instructions over a network to the controller 470.

The controller 470 may be locally located relative to the thermal processing system 400, or it may be remotely located relative to the thermal processing system 400. For example, the controller 470 may exchange data with the thermal processing system 400 using at least one of a direct connection, an intranet, the Internet and a wireless connection. The controller 470 may be coupled to an intranet at, for example, a customer site (i.e., a device maker, etc.), or it may be coupled to an intranet at, for example, a vendor site (i.e., an equipment manufacturer). Additionally, for example, the controller 470 may be coupled to the Internet. Furthermore, another computer (i.e., controller, server, etc.) may access, for example, the controller 470 to exchange data via at least one of a direct connection, an intranet, and the Internet. As also would be appreciated by those skilled in the art, the controller 470 may exchange data with the thermal processing system 400 via a wireless connection.

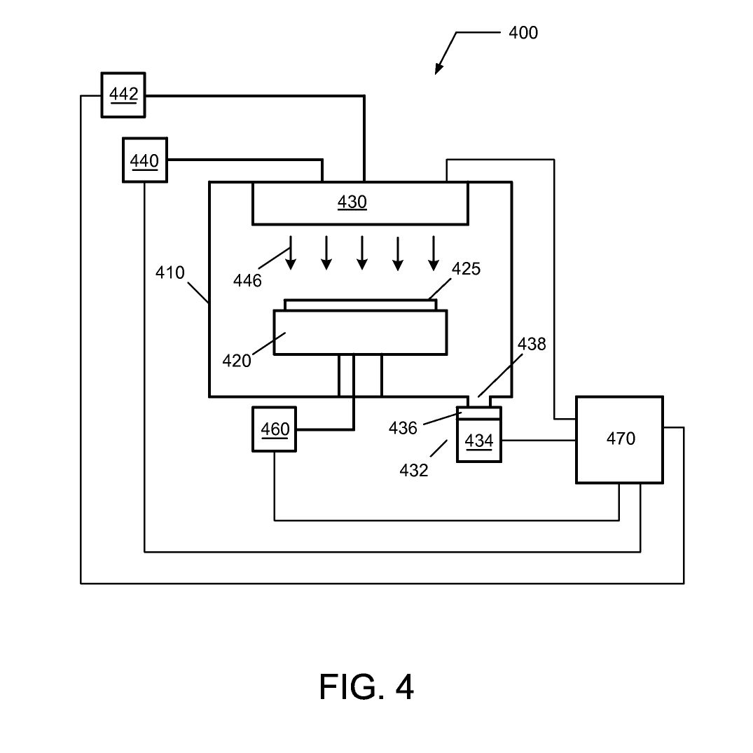

FIG. 5 depicts a schematic view of a thermal chemical vapor deposition (TCVD) system 1 for depositing a Ru metal film from a Ru₃(CO)₁₂ precursor vapor and a CO gas according to an embodiment of the invention. The deposition system 1 includes a process chamber 10 having a substrate holder 20 configured to support a patterned substrate 25 upon which the Ru metal film is formed. The process chamber 10 is coupled to a metal precursor vaporization system 50 via a vapor precursor delivery system 40.

The process chamber 10 is further coupled to a vacuum pumping system 38 through a duct 36, wherein the vacuum pumping system 38 is configured to evacuate the process chamber 10, vapor precursor delivery system 40, and metal precursor vaporization system 50 to a pressure suitable for forming the Ru metal film on the patterned substrate 25, and suitable for vaporization of the Ru₃(CO)₁₂ precursor 52 in the metal precursor vaporization system 50.

Still referring to FIG. 5, the metal precursor vaporization system 50 is configured to store a Ru₃(CO)₁₂ precursor 52, to heat the Ru₃(CO)₁₂ precursor 52 to a temperature sufficient for vaporizing the Ru₃(CO)₁₂ precursor 52, and to introduce Ru₃(CO)₁₂ precursor vapor to the vapor precursor delivery system 40. The Ru₃(CO)₁₂ precursor 52 is a solid under the selected heating conditions in the metal precursor vaporization system 50. In order to achieve the desired temperature for subliming the solid Ru₃(CO)₁₂ precursor 52, the metal precursor vaporization system 50 is coupled to a vaporization temperature control system 54 configured to control the vaporization temperature.

For instance, the temperature of the Ru₃(CO)₁₂ precursor 52 may be elevated to between approximately 40° C. to approximately 150° C. Alternately, the vaporization temperature can be maintained at approximately 60° C. to approximately 90° C. As the Ru₃(CO)₁₂ precursor 52 is heated to cause sublimation, a CO-containing gas is passed over or through the Ru₃(CO)₁₂ precursor 52 to capture the Ru₃(CO)₁₂ precursor vapor as it is being formed. The CO-containing gas contains CO and optionally an inert carrier gas, such as N₂, or a noble gas (i.e., He, Ne, Ar, Kr, or Xe), or a combination thereof. Vaporizing the Ru₃(CO)₁₂ precursor in the presence of CO gas can reduce problems that limit the delivery of the Ru₃(CO)₁₂ precursor vapor to the patterned substrate. It has been shown that addition of the CO gas to the Ru₃(CO)₁₂ precursor vapor as it is being formed allows for increasing the vaporization temperature. The elevated temperature increases the vapor pressure of the Ru₃(CO)₁₂ precursor, resulting in increased delivery of the Ru₃(CO)₁₂ precursor to the process chamber and, hence, increased deposition rate of a Ru metal film on the patterned substrate 25. The use of a CO gas to reduce premature decomposition of the Ru₃(CO)₁₂ precursor in the vapor precursor delivery system 40 prior to delivery of the Ru₃(CO)₁₂ precursor to the process chamber 10 has been shown to facilitate efficient transfer of Ru₃(CO)₁₂ precursor vapor to a process chamber to deposit Ru metal film has been described in U.S. Pat. No. 7,270,848, the entire contents of which is incorporated herein by reference.

In one example, the metal precursor vaporization system 50 may be a multi-tray vaporization system configured for efficient evaporation and transport of the Ru₃(CO)₁₂ vapor. An exemplary multi-tray vaporization system is described in U.S. Pat. No. 7,638,002.

For example, a gas supply system 60 is coupled to the metal precursor vaporization system 50, and the gas supply system 60 is configured to, for instance, supply CO, a carrier gas, or a mixture thereof, beneath the Ru₃(CO)₁₂ precursor 52 via feed line 61, or over the Ru₃(CO)₁₂ precursor 52 via feed line 62. In addition, the gas supply system 60 is coupled to the vapor precursor delivery system 40 downstream from the metal precursor vaporization system 50 to supply the gas to the vapor of the Ru₃(CO)₁₂ precursor 52 via feed line 63 as or after it enters the vapor precursor delivery system 40. Furthermore, the feed line 63 may be utilized to pre-treat the patterned substrate 25 with a pre-treatment gas containing CO gas to saturate the exposed surfaces of the patterned substrate 25 with adsorbed CO prior to exposing the patterned substrate 25 to Ru₃(CO)₁₂ precursor vapor and CO gas.

Although not shown, the gas supply system 60 can comprise a carrier gas source, a CO gas source, one or more control valves, one or more filters, and a mass flow controller. For instance, the flow rate of the CO-containing gas can be between about 0.1 standard cubic centimeters per minute (sccm) and about 1000 sccm. Alternately, the flow rate of the CO-containing gas can be between about 10 sccm and about 500 sccm. Still alternately, the flow rate of the CO-containing gas can be between about 50 sccm and about 200 sccm. According to embodiments of the invention, the flow rate of the CO-containing gas can range from approximately 0.1 sccm to approximately 1000 sccm. Alternately, the flow rate of the CO-containing gas can be between about 1 sccm and about 500 sccm.

Downstream from the metal precursor vaporization system 50, the process gas containing the Ru₃(CO)₁₂ precursor vapor and CO gas flows through the vapor precursor delivery system 40 until the process gas enters the process chamber 10 via a vapor distribution system 30 coupled thereto. The vapor precursor delivery system 40 can be coupled to a vapor line temperature control system 42 in order to control the vapor line temperature and prevent decomposition of the Ru₃(CO)₁₂ precursor vapor as well as condensation of the Ru₃(CO)₁₂ precursor vapor. The vapor precursor delivery system 40 can, for example, be maintained at a temperature between 50° C. and 100° C.

Still referring to FIG. 5, the vapor distribution system 30, which forms part of and is coupled to the process chamber 10, comprises a vapor distribution plenum 32 within which the vapor disperses prior to passing through a vapor distribution plate 34 and entering a processing zone 33 above the patterned substrate 25. In addition, the vapor distribution plate 34 can be coupled to a distribution plate temperature control system 35 configured to control the temperature of the vapor distribution plate 34.

Once the process gas containing the Ru₃(CO)₁₂ precursor vapor and CO gas enters the processing zone 33 of process chamber 10, the Ru₃(CO)₁₂ precursor vapor thermally decomposes upon adsorption at the substrate surface due to the elevated temperature of the patterned substrate 25, and a Ru metal film is formed on the patterned substrate 25. The substrate holder 20 is configured to elevate the temperature of the patterned substrate 25 by virtue of the substrate holder 20 being coupled to a substrate temperature control system 22. For example, the substrate temperature control system 22 can be configured to elevate the temperature of the patterned substrate 25 up to approximately 500° C. Additionally, the process chamber 10 can be coupled to a chamber temperature control system 12 configured to control the temperature of the chamber walls.

Still referring to FIG. 5, the deposition system 1 can further include a control system 80 configured to operate and control the operation of the deposition system 1. The control system 80 is coupled to the process chamber 10, the substrate holder 20, the substrate temperature control system 22, the chamber temperature control system 12, the vapor distribution system 30, the vapor precursor delivery system 40, the metal precursor vaporization system 50, and the gas supply system 60.

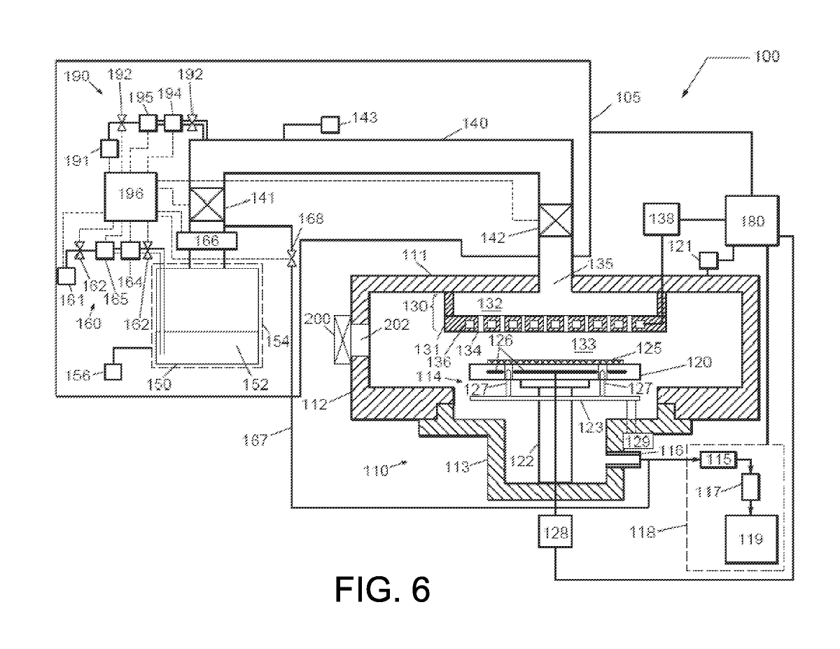

FIG. 6 depicts a schematic view of another TCVD system for depositing a Ru metal film from a Ru₃(CO)₁₂ precursor vapor and a CO gas according to an embodiment of the invention. The deposition system 100 comprises a process chamber 110 having a substrate holder 120 configured to support a patterned substrate 125 upon which the Ru metal film is formed. The process chamber 110 is coupled to a precursor delivery system 105 having metal precursor vaporization system 150 configured to store and vaporize a Ru₃(CO)₁₂ precursor 152, and a vapor precursor delivery system 140 configured to transport the vapor of the Ru₃(CO)₁₂ precursor 152 to the process chamber 110.

The process chamber 110 comprises an upper chamber section 111, a lower chamber section 112, and an exhaust chamber 113. An opening 114 is formed within lower chamber section 112, where lower chamber section 112 couples with exhaust chamber 113.

Still referring to FIG. 6, substrate holder 120 provides a horizontal surface to support a patterned substrate (or wafer) 125, which is to be processed. The substrate holder 120 can be supported by a cylindrical support member 122, which extends upward from the lower portion of exhaust chamber 113. Furthermore, the substrate holder 120 comprises a heater 126 coupled to substrate holder temperature control system 128. The heater 126 can, for example, include one or more resistive heating elements. Alternately, the heater 126 can, for example, include a radiant heating system, such as a tungsten-halogen lamp. The substrate holder temperature control system 128 can include a power source for providing power to the one or more heating elements, one or more temperature sensors for measuring the substrate temperature or the substrate holder temperature, or both, and a controller configured to perform at least one of monitoring, adjusting, or controlling the temperature of the patterned substrate 125 or substrate holder 120.

During processing, the heated patterned substrate 125 can thermally decompose the Ru₃(CO)₁₂ precursor vapor, and enable deposition of a Ru metal film on the patterned substrate 125. The substrate holder 120 is heated to a pre-determined temperature that is suitable for depositing the desired Ru metal film onto the patterned substrate 125. Additionally, a heater (not shown) coupled to a chamber temperature control system 121 can be embedded in the walls of process chamber 110 to heat the chamber walls to a pre-determined temperature. The heater can maintain the temperature of the walls of process chamber 110 from about 40° C. to about 150° C., or from about 40° C. to about 80° C. A pressure gauge (not shown) is used to measure the process chamber pressure. According to an embodiment of the invention, the process chamber pressure can be between about 1 mTorr and about 500 mTorr. Alternately, the process chamber pressure can be between about 10 mTorr and about 100 mTorr.

Also shown in FIG. 6, a vapor distribution system 130 is coupled to the upper chamber section 111 of process chamber 110. Vapor distribution system 130 comprises a vapor distribution plate 131 configured to introduce precursor vapor from vapor distribution plenum 132 to a processing zone 133 above the patterned substrate 125 through one or more orifices 134.

Furthermore, an opening 135 is provided in the upper chamber section 111 for introducing a process gas containing Ru₃(CO)₁₂ precursor vapor and CO gas from vapor precursor delivery system 140 into vapor distribution plenum 132. Moreover, temperature control elements 136, such as concentric fluid channels configured to flow a cooled or heated fluid, are provided for controlling the temperature of the vapor distribution system 130, and thereby prevent the decomposition or condensation of the Ru₃(CO)₁₂ precursor vapor inside the vapor distribution system 130. For instance, a fluid, such as water, can be supplied to the fluid channels from a vapor distribution temperature control system 138. The vapor distribution temperature control system 138 can include a fluid source, a heat exchanger, one or more temperature sensors for measuring the fluid temperature or vapor distribution plate temperature or both, and a controller configured to control the temperature of the vapor distribution plate 131 from about 20° C. to about 150° C. For a Ru₃(CO)₁₂ precursor, the temperature of the vapor distribution plate 131 can be maintained at or above a temperature of about 65° C. to avoid precursor condensation on the vapor distribution plate 131.

As illustrated in FIG. 6, a metal precursor vaporization system 150 is configured to hold a Ru₃(CO)₁₂ precursor 152 and to evaporate (or sublime) the Ru₃(CO)₁₂ precursor 152 by elevating the temperature of the Ru₃(CO)₁₂ precursor. The terms “vaporization,” “sublimation” and “evaporation” are used interchangeably herein to refer to the general formation of a vapor (gas) from a solid or liquid precursor, regardless of whether the transformation is, for example, from solid to liquid to gas, solid to gas, or liquid to gas. A precursor heater 154 is provided for heating the Ru₃(CO)₁₂ precursor 152 to maintain the Ru₃(CO)₁₂ precursor 152 at a temperature that produces a desired vapor pressure of Ru₃(CO)₁₂ precursor 152. The precursor heater 154 is coupled to a vaporization temperature control system 156 configured to control the temperature of the Ru₃(CO)₁₂ precursor 152. For example, the precursor heater 154 can be configured to adjust the temperature of the Ru₃(CO)₁₂ precursor 152 from about 40° C. to about 150° C., or from about 60° C. to about 90° C.

As the Ru₃(CO)₁₂ precursor 152 is heated to cause evaporation (or sublimation), a CO-containing gas can be passed over or through the Ru₃(CO)₁₂ precursor 152 to capture the Ru₃(CO)₁₂ precursor vapor as the Ru₃(CO)₁₂ precursor vapor is being formed. The CO-containing gas contains CO and optionally an inert carrier gas, such as N₂, or a noble gas (i.e., He, Ne, Ar, Kr, Xe). For example, a gas supply system 160 is coupled to the metal precursor vaporization system 150, and is configured to, for instance, flow the CO gas over or through the Ru₃(CO)₁₂ precursor 152. Although not shown in FIG. 6, gas supply system 160 can also be coupled to the vapor precursor delivery system 140 to supply the CO gas to the vapor of the Ru₃(CO)₁₂ precursor 152 as or after the vapor of the Ru₃(CO)₁₂ precursor 152 enters the vapor precursor delivery system 140, for example, to pre-treat the patterned substrate 125 with a pre-treatment gas containing CO gas to saturate the exposed surfaces of the patterned substrate 125 with adsorbed CO prior to exposing the patterned substrate 125 to a process gas containing Ru₃(CO)₁₂ precursor vapor and CO gas.

The gas supply system 160 can comprise a gas source 161 containing an inert carrier gas, a CO gas, or a mixture thereof, one or more control valves 162, one or more filters 164, and a mass flow controller 165. For instance, the mass flow rate of the CO-containing gas can range from approximately 0.1 sccm to approximately 1000 sccm.

Additionally, a sensor 166 is provided for measuring the total gas flow from the metal precursor vaporization system 150. The sensor 166 can, for example, comprise a mass flow controller, and the amount of Ru₃(CO)₁₂ precursor vapor delivered to the process chamber 110 can be determined using sensor 166 and mass flow controller 165. Alternately, the sensor 166 can comprise a light absorption sensor to measure the concentration of the Ru₃(CO)₁₂ precursor in the gas flow to the process chamber 110.

A bypass line 167 can be located downstream from sensor 166, and the bypass line 167 can connect the vapor precursor delivery system 140 to an exhaust line 116. Bypass line 167 is provided for evacuating the vapor precursor delivery system 140, and for stabilizing the supply of the Ru₃(CO)₁₂ precursor vapor and CO gas to the process chamber 110. In addition, a bypass valve 168, located downstream from the branching of the vapor precursor delivery system 140, is provided on bypass line 167.

Referring still to FIG. 6, the vapor precursor delivery system 140 comprises a high conductance vapor line having first and second valves 141 and 142, respectively. Additionally, the vapor precursor delivery system 140 can further comprise a vapor line temperature control system 143 configured to heat the vapor precursor delivery system 140 via heaters (not shown). The temperatures of the vapor lines can be controlled to avoid condensation of the Ru₃(CO)₁₂ precursor vapor in the vapor line. The temperature of the vapor lines can be controlled from about 20° C. to about 100° C., or from about 40° C. to about 90° C.

Moreover, a CO gas can be supplied from a gas supply system 190. For example, the gas supply system 190 is coupled to the vapor precursor delivery system 140, and it is configured to, for instance, pre-treat the patterned substrate 125 with a pre-treatment gas containing a CO gas or mix additional CO gas with the Ru₃(CO)₁₂ precursor vapor in the vapor precursor delivery system 140, for example, downstream of valve 141. The gas supply system 190 can comprise a CO gas source 191, one or more control valves 192, one or more filters 194, and a mass flow controller 195. For instance, the mass flow rate of CO gas can range from approximately 0.1 sccm to approximately 1000 sccm.

Mass flow controllers 165 and 195, and valves 162, 192, 168, 141, and 142 are controlled by controller 196, which controls the supply, shutoff, and the flow of the inert carrier gas, the CO gas, and the Ru₃(CO)₁₂ precursor vapor. Sensor 166 is also connected to controller 196 and, based on output of the sensor 166, controller 196 can control the carrier gas flow through mass flow controller 165 to obtain the desired Ru₃(CO)₁₂ precursor flow to the process chamber 110.

As illustrated in FIG. 6, the exhaust line 116 connects exhaust chamber 113 to vacuum pumping system 118. A vacuum pump 119 is used to evacuate process chamber 110 to the desired degree of vacuum, and to remove gaseous species from the process chamber 110 during processing. An automatic pressure controller (APC) 115 and a trap 117 can be used in series with the vacuum pump 119. The vacuum pump 119 can include a turbo-molecular pump (TMP) capable of a pumping speed up to 500 liters per second (and greater). Alternately, the vacuum pump 119 can include a dry roughing pump. During processing, the process gas can be introduced into the process chamber 110, and the chamber pressure can be adjusted by the APC 115. The APC 115 can comprise a butterfly-type valve or a gate valve. The trap 117 can collect unreacted Ru₃(CO)₁₂ precursor material and by-products from the process chamber 110.

Referring back to the substrate holder 120 in the process chamber 110, as shown in FIG. 6, three substrate lift pins 127 (only two are shown) are provided for holding, raising, and lowering the patterned substrate 125. The substrate lift pins 127 are coupled to plate 123, and can be lowered to below the upper surface of substrate holder 120. A drive mechanism 129 utilizing, for example, an air cylinder provides means for raising and lowering the plate 123. The patterned substrate 125 can be transferred into and out of process chamber 110 through gate valve 200 and chamber feed-through passage 202 via a robotic transfer system (not shown), and received by the substrate lift pins 127. Once the patterned substrate 125 is received from the transfer system, the patterned substrate 125 can be lowered to the upper surface of the substrate holder 120 by lowering the substrate lift pins 127.

Still referring to FIG. 6, a deposition system controller 180 includes a microprocessor, a memory, and a digital I/O port capable of generating control voltages sufficient to communicate and activate inputs of the deposition system 100 as well as monitor outputs from the deposition system 100. Moreover, the controller 180 is coupled to and exchanges information with process chamber 110; precursor delivery system 105, which includes controller 196, vapor line temperature control system 143, and vaporization temperature control system 156; vapor distribution temperature control system 138; vacuum pumping system 118; and substrate holder temperature control system 128. In the vacuum pumping system 118, the controller 180 is coupled to and exchanges information with the APC 115 for controlling the pressure in the process chamber 110. A program stored in the memory is utilized to control the aforementioned components of the deposition system 100 according to a stored process recipe.

The controller 180 may be implemented as a general purpose computer system that performs a portion or all of the microprocessor-based processing steps of the invention in response to a processor executing one or more sequences of one or more instructions contained in a memory. Such instructions may be read into the controller memory from another computer readable medium, such as a hard disk or a removable media drive. One or more processors in a multi-processing arrangement may also be employed as the controller microprocessor to execute the sequences of instructions contained in main memory. In alternative embodiments, hard-wired circuitry may be used in place of or in combination with software instructions. Thus, embodiments are not limited to any specific combination of hardware circuitry and software.

The controller 180 includes at least one computer readable medium or memory, such as the controller memory, for holding instructions programmed according to the teachings of the invention and for containing data structures, tables, records, or other data that may be necessary to implement the present invention. Examples of computer readable media are compact discs, hard disks, floppy disks, tape, magneto-optical disks, PROMs (EPROM, EEPROM, flash EPROM), DRAM, SRAM, SDRAM, or any other magnetic medium, compact discs (e.g., CD-ROM), or any other optical medium, punch cards, paper tape, or other physical medium with patterns of holes, a carrier wave (described below), or any other medium from which a computer can read.

Stored on any one or on a combination of computer readable media, the present invention includes software for controlling the controller 180, for driving a device or devices for implementing the invention, and/or for enabling the controller to interact with a human user. Such software may include, but is not limited to, device drivers, operating systems, development tools, and applications software. Such computer readable media further includes the computer program product of the present invention for performing all or a portion (if processing is distributed) of the processing performed in implementing the invention.

The computer code devices of the present invention may be any interpretable or executable code mechanism, including but not limited to scripts, interpretable programs, dynamic link libraries (DLLs), Java classes, and complete executable programs. Moreover, parts of the processing of the present invention may be distributed for better performance, reliability, and/or cost.

The term “computer readable medium” as used herein refers to any medium that participates in providing instructions to the processor of the controller 180 for execution. A computer readable medium may take many forms, including but not limited to, non-volatile media, volatile media, and transmission media. Non-volatile media includes, for example, optical disks, magnetic disks, and magneto-optical disks, such as the hard disk or the removable media drive. Volatile media includes dynamic memory, such as the main memory. Moreover, various forms of computer readable media may be involved in carrying out one or more sequences of one or more instructions to the processor of the controller for execution. For example, the instructions may initially be carried on a magnetic disk of a remote computer. The remote computer can load the instructions for implementing all or a portion of the present invention remotely into a dynamic memory and send the instructions over a network to the controller 180.

The controller 180 may be locally located relative to the deposition system 100, or the controller 180 may be remotely located relative to the deposition system 100. For example, the controller 180 may exchange data with the deposition system 100 using at least one of a direct connection, an intranet, the Internet or a wireless connection. The controller 180 may be coupled to an intranet at, for example, a customer site (i.e., a device maker, etc.), or it may be coupled to an intranet at, for example, a vendor site (i.e., an equipment manufacturer). Additionally, for example, the controller 180 may be coupled to the Internet. Furthermore, another computer (i.e., controller, server, etc.) may access, for example, the controller 180 to exchange data via at least one of a direct connection, an intranet, and the Internet. As also would be appreciated by those skilled in the art, the controller 180 may exchange data with the deposition system 100 via a wireless connection.

A plurality of embodiments for forming a semiconductor device have been disclosed in various embodiments. The foregoing description of the embodiments of the invention has been presented for the purposes of illustration and description. It is not intended to be exhaustive or to limit the invention to the precise forms disclosed. This description and the claims following include terms that are used for descriptive purposes only and are not to be construed as limiting. For example, the term “on” as used herein (including in the claims) does not require that a film “on” a patterned substrate is directly on and in immediate contact with the substrate; there may be a second film or other structure between the film and the substrate.

Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

1. A method of forming a semiconductor device, comprising:
providing a planarized patterned substrate containing a copper (Cu) metal surface and a low-k dielectric layer surface;
selectively depositing a metal cap layer on the Cu metal surface;
modifying the metal cap layer by exposing the metal cap layer to a process gas containing ammonia (NH₃) gas without plasma excitation;
forming a dielectric barrier film on the modified metal cap layer and on the dielectric layer surface; and
exposing the dielectric barrier film to a gaseous oxidizing environment, wherein the dielectric barrier film and the modified metal cap layer prevent oxidation of the Cu metal surface when the dielectric barrier film is exposed to the gaseous oxidizing environment.

2. The method of claim 1, wherein the metal cap layer comprises a metal selected from ruthenium (Ru), rhodium (Rh), platinum (Pt), palladium (Pd), or an alloy thereof.

3. The method of claim 2, wherein the metal cap layer has a thickness less than 15 nm.

4. The method of claim 3, wherein the dielectric barrier film has a thickness less than 15 nm.

5. The method of claim 4, wherein a combined thickness of the metal cap layer and the dielectric barrier film is less than 20 nm.

6. The method of claim 1, wherein the dielectric barrier film contains silicon nitride (SiN), silicon carbide (SiC), silicon carbonitride (SiCN), or a combination thereof.

7. The method of claim 1, wherein the process gas further comprises a noble gas or N₂.

8. The method of claim 1, wherein the selectively depositing comprises a thermal chemical vapor deposition (TCVD) process performed without plasma excitation.

9. A method of forming a semiconductor device, comprising:
providing a planarized patterned substrate containing a copper (Cu) metal surface and a low-k dielectric layer surface;
selectively depositing a metal cap layer on the Cu metal surface, wherein the metal cap layer comprises a metal selected from ruthenium (Ru), rhodium (Rh), platinum (Pt), palladium (Pd), or an alloy thereof;
modifying the metal cap layer by exposing the metal cap layer to a process gas containing ammonia (NH₃) gas without plasma excitation;
forming a dielectric barrier film containing silicon (Si) on the modified metal cap layer and on the low-k dielectric layer surface; and
exposing the dielectric barrier film to a gaseous oxidizing environment, wherein a combined thickness of the metal cap layer and the dielectric barrier film is less than 20 nm, and wherein the method of forming a semiconductor device by forming a modified metal cap layer prevents oxidation of the Cu metal surface when compared to a method of forming a semiconductor device using an unmodified metal cap layer.

10. The method of claim 9, wherein the selectively depositing comprises a thermal chemical vapor deposition (TCVD) process performed without plasma excitation.

11. The method of claim 9, wherein the dielectric barrier film contains silicon nitride (SiN), silicon carbide (SiC), silicon carbonitride (SiCN), or a combination thereof.

12. The method of claim 9, wherein the metal cap layer has a thickness less than 15 nm and the dielectric barrier film has a thickness less than 15 nm.

13. The method of claim 12, wherein a combined thickness of the metal cap layer and the dielectric barrier film is less than 20 nm.

14. A method of forming a semiconductor device, comprising:
providing a planarized patterned substrate containing a copper (Cu) metal surface and a low-k dielectric layer surface;
selectively depositing a ruthenium (Ru) metal cap layer on the Cu metal surface by a thermal chemical vapor deposition (TCVD) process performed without plasma excitation;
modifying the Ru metal cap layer by exposing the metal cap layer to a process gas containing ammonia (NH₃) gas without plasma excitation;
forming a dielectric barrier film on the modified metal cap layer and on the dielectric layer surface; and
exposing the dielectric barrier film to a gaseous oxidizing environment, wherein the dielectric barrier film and the modified metal cap layer prevent oxidation of the Cu metal surface when the dielectric barrier film is exposed to the gaseous oxidizing environment.

15. The method of claim 14, wherein the metal cap layer has a thickness less than 15 nm.

16. The method of claim 15, wherein the dielectric barrier film has a thickness less than 15 nm.

17. The method of claim 16, wherein a combined thickness of the metal cap layer and the dielectric barrier film is less than 20 nm.

18. The method of claim 14, wherein the dielectric barrier film includes silicon nitride (SiN), silicon carbide (SiC), silicon carbonitride (SiCN), or a combination thereof.

19. The method of claim 14, wherein the selectively depositing a Ru metal cap layer comprises exposing the planarized patterned substrate to a deposition gas containing Ru₃(CO)₁₂ and CO.

20. The method of claim 14, wherein the process gas containing ammonia (NH₃) gas consists of NH₃ or NH₃ and an inert gas.
